(19) United States
(12) Patent Application Publication
(10) Pub. No.: US 2026/0247953 A1
(43) Pub. Date: Aug. 20, 2026

(54) BACKSIDE GATE CONTACT FORMED BY DIRECT BACKSIDE ETCHING

(71) Applicant: Intel Corporation, Santa Clara, CA (US)

(72) Inventors: Ehren Mannebach, Beaverton, OR (US); Shaun Mills, Hillsboro, OR (US); Joseph D'Silva, Hillsboro, OR (US); Mauro J. Kobrinsky, Portland, OR (US)

(73) Assignee: Intel Corporation, Santa Clara, CA (US)

(21) Appl. No.: 19/057,157

(22) Filed: Feb. 19, 2025

(51) Int. Cl. H01L 23/528; H10D 84/83

(52) U.S. Cl. CPC H10W 20/435; H10D 84/832

(57) ABSTRACT

Techniques are provided herein to form an integrated circuit having backside conductive contacts beneath gate structures. Backside cavities beneath the gate structures are formed using backside lithography and anisotropic etching. The backside cavities are subsequently filled with a conductive material to form the backside contacts. A semiconductor device includes a gate structure around or otherwise on a semiconductor region that extends from a first source or drain region to a second source or drain region. The substrate beneath the semiconductor device is removed from the backside to expose a subfin region that is also removed using a backside etch and replaced with a dielectric material. Suitable lithographic operations may be performed on the backside dielectric material along with an anisotropic etch to form any number of cavities through the dielectric material. The backside conductive contacts are then formed within the backside cavities.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Due to the small size of the transistor elements, such as the transistor gate, source, or drain, it can be difficult to provide effective contacts while maintaining desired operation speeds and power requirements. Accordingly, there remain a number of non-trivial challenges with respect to forming such high-density semiconductor devices.

### BRIEF DESCRIPTION OF THE DRAWINGS

FIG. 1 is a cross-sectional view of different semiconductor devices in an integrated circuit that include at least one backside gate contact, in accordance with an embodiment of the present disclosure.

FIG. 2A-2N are cross-sectional views that illustrate different stages in an example process for forming an integrated circuit having a backside gate contact, in accordance with some embodiments of the present disclosure.

FIG. 3 is a cross-sectional view of the integrated circuit having the backside gate contact coupled to a backside interconnect network, in accordance with an embodiment of the present disclosure.

FIG. 4 is a cross-sectional view of the integrated circuit having the backside gate contact coupled to a backside interconnect network and a frontside contact coupled to a frontside interconnect network, in accordance with an embodiment of the present disclosure.

FIG. 4′ is another cross-sectional view of the integrated circuit having the backside contact and frontside contact coupled to either end of a conductive feedthrough structure, in accordance with an embodiment of the present disclosure.

FIG. 5 illustrates a cross-sectional view of a chip package containing one or more semiconductor dies, in accordance with some embodiments of the present disclosure.

FIG. 6 is a flowchart of a fabrication process for semiconductor devices having at least one backside gate contact, in accordance with an embodiment of the present disclosure.

FIG. 7 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having one or more backside conductive contacts beneath one or more corresponding gate structures. According to some embodiments, backside cavities beneath the gate structures are formed using backside lithography and any suitable anisotropic etching technique. The backside cavities are then subsequently filled with a conductive material to form the backside contacts. The techniques can be used in any number of integrated circuit applications and are particularly useful with respect to logic and memory cells, such as those cells that use finFETs, gate-all-around transistors (e.g., ribbonFETs and nanowire FETs), or forksheet transistors. In an example, a semiconductor device includes a gate structure around or otherwise on a semiconductor region. The semiconductor region can be, for example, a fin of semiconductor material that extends from a first source or drain region to a second source or drain region, or one or more nanowires, nanoribbon, or nanosheets of semiconductor material that extend from a first source or drain region to a second source or drain region. The gate structure includes a gate dielectric (e.g., high-k gate dielectric material) and a gate electrode (e.g., conductive material such as workfunction material and/or gate fill metal). The substrate beneath the semiconductor device may be removed from the backside to expose a subfin region beneath the semiconductor region. The subfin region may be removed using a backside etch and replaced with a dielectric material. Suitable lithographic operations may be performed on the backside dielectric material along with an anisotropic etch to form a cavity through the dielectric material and expose a bottom surface of a given gate electrode (after also etching through the gate dielectric). One or more conductive materials may be formed within the cavity to create the backside contact on the bottom surface of the gate electrode. Numerous variations and embodiments will be apparent in light of this disclosure.

### General Overview

As previously noted above, there remain a number of non-trivial challenges with respect to integrated circuit fabrication. In more detail, backside interconnects have become increasingly more popular to route power and ground rails beneath regions of various transistors. One way to contact a given source or drain region from the backside is to use front-side processing operations to remove a portion of a subfin and replace the removed portion with a sacrificial material. The source or drain region is then formed over the sacrificial material, and the sacrificial material is later removed from the backside to expose the bottom surface of the source or drain region. However, there is not a similar front-side process for forming contacts beneath gate structures. Thus, gate structures are contacted using front-side contacts, which can increase the routing complexity for front-side interconnects and produce inefficient routing designs.

Thus, and in accordance with an embodiment of the present disclosure, techniques are provided herein to use lithographic operations to directly etch one or more cavities through a backside dielectric layer to expose the bottom surfaces of one or more corresponding gate structures. The cavities may then be filled with any number of conductive materials to form the backside contacts. According to some embodiments, a reactive ion etching (RIE) processing may be used on the backside to expose the bottom surface of the gate structure, which yields a backside cavity having inwardly tapered sidewalls. Due to this tapering, the width of the resulting backside contact also tapers such that a bottom surface of the backside contact (e.g., away from the gate structure) is wider (e.g., at least 3 nm wider) than a width of the backside contact at the bottom surface of the gate structure. The location of the backside contact may be lithographically patterned to land within the width of the gate structure, which may be less than 30 nm, such as between 15 nm and 25 nm. In some embodiments, backside contacts are lithographically patterned beneath a conductive feedthrough structure (e.g., a dummy gate with the semiconductor channel regions removed).

According to an embodiment, an integrated circuit includes a semiconductor device having a semiconductor region extending in a first direction from a first source or drain region to a second source or drain region and a gate structure extending in a second direction, different from the first direction, over the semiconductor region, a dielectric layer beneath the gate structure, and a backside conductive contact extending through the dielectric layer and contacting a bottom surface of the gate structure. The backside conductive contact has a tapered width along the first direction such that a first width of the backside conductive contact at a bottom surface of the dielectric layer is greater than a second width of the backside conductive contact at the bottom surface of the gate structure.

According to another embodiment, an electronic device includes a chip package having one or more dies. At least one of the one or more dies includes a semiconductor region extending in a first direction from a first source or drain region to a second source or drain region, a gate structure extending in a second direction, different from the first direction, over the semiconductor region, a dielectric layer beneath the gate structure, and a backside conductive contact extending through the dielectric layer and contacting a bottom surface of the gate structure. The gate structure has a width along the first direction that is no greater than 30 nm.

According to another embodiment, a method of forming an integrated circuit includes: forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; forming a source or drain region at exposed ends of the semiconductor material and over the subfin; replacing the sacrificial gate with a gate structure; removing a portion of the substrate from a backside of the integrated circuit; removing the subfin from the backside and replacing the subfin with a dielectric fill; etching a cavity through the dielectric fill such that a bottom surface of the gate structure is exposed; and forming a conductive contact in the cavity.

According to another embodiment, an integrated circuit includes a first semiconductor device having a first semiconductor region extending in a first direction from a first source or drain region, a second semiconductor device having a second semiconductor region extending in the first direction from a second source or drain region, a conductive structure between the first source or drain region and the second source or drain region along the first direction, a first dielectric layer beneath the conductive structure, a second dielectric layer above the conductive structure, a backside conductive contact extending through the first dielectric layer and contacting a bottom surface of the conductive structure, and a frontside conductive contact extending through the second dielectric layer and contacting a top surface of the conductive structure. The backside conductive contact has a tapered width along the first direction such that a first width of the backside conductive contact at a bottom surface of the first dielectric layer is greater than a second width of the backside conductive contact at the bottom surface of the conductive structure.

The techniques can be used with any type of non-planar transistors, including finFETs (sometimes called double-gate transistors, or tri-gate transistors), or nanowire and nanoribbon transistors (sometimes called gate-all-around transistors), or stacked versions of any of these architectures, to name a few examples. The source and drain regions can be, for example, doped portions of a given fin or substrate or epitaxial regions that are deposited during an etch-and-replace source/drain forming process. The dopant type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of backside contacts beneath one or more gate structures. The backside contacts would have a tapered profile that is indicative a backside RIE process (e.g., the width of the contact decreases as it rises up towards the bottom surface of the gate structure).

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer. Multiple formed layers of the same material (e.g., a same dielectric material) on one another may be collectively considered a single layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

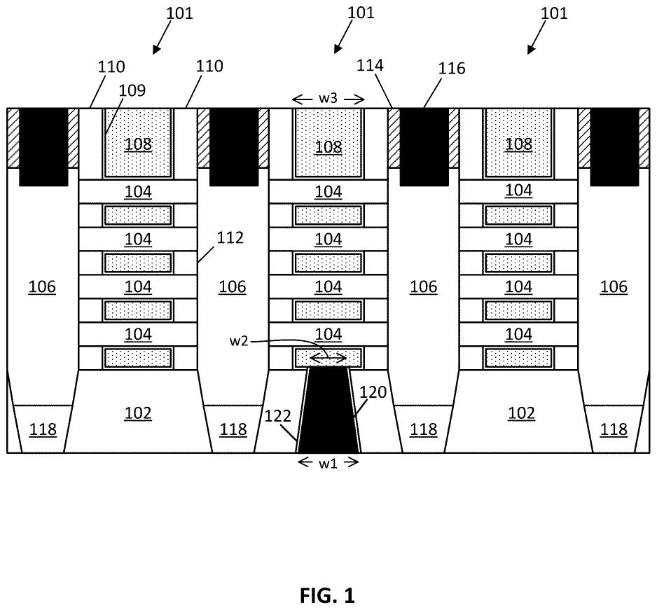

FIG. 1 is a cross-section view taken through semiconductor devices 101 along a ‘fin’ direction that illustrates the semiconductor bodies extending between source or drain regions of each of the semiconductor devices, in accordance with an embodiment of the present disclosure. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure. Any of semiconductor devices 101 may be p-channel devices (e.g., PMOS) or n-channel devices (e.g., NMOS).

The semiconductor material used in each of the semiconductor devices may be formed from or on a semiconductor substrate. According to some embodiments, the substrate is removed following the completion of all topside processing and is replaced with a base dielectric layer 102. Base dielectric layer 102 may represent any number of dielectric layers and/or materials. In some examples, base dielectric layer 102 includes one or more layers of silicon dioxide.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Semiconductor devices 101 include one or more semiconductor regions (also called channel regions), such as one or more nanoribbons 104 extending between epitaxial source or drain regions 106 in the first direction. Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. In an example, p-channel devices have a high concentration of p-type dopants in the associated source or drain regions 106, and n-channel devices have a high concentration of n-type dopants in the associated source or drain regions 106. Example p-type dopants include boron and example n-type dopants include phosphorous or arsenic. Any number of source and drain configurations and materials can be used. In some examples, p-type source or drain regions 106 include silicon germanium doped with boron and n-type source or drain regions 106 include silicon doped with phosphorous.

A gate structure extends over nanoribbons 104 of each semiconductor device 101 in a second direction (e.g., into and out of the page) to form the transistor gate of each corresponding semiconductor device 101. Each gate structure may include a corresponding gate electrode 108 and gate dielectric 109. Gate electrode 108 may be made up of a conductive fill and one or more metal workfunction layers, according to some embodiments. Gate dielectric 109 may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, p-channel devices have a gate electrode 108 with one or more workfunction layers of molybdenum nitride (MoN). Other metal workfunction layers of p-channel devices can include tantalum nitride (TaN) and tungsten (W. In some embodiments, n-channel devices have a gate electrode 108 with one or more workfunction layers of titanium aluminum carbide. Other metal workfunction layers of n-channel devices can include tantalum nitride (TaN).

Gate dielectric 109 may include any suitable gate dielectric material(s). In some embodiments, gate dielectric 109 includes a layer of native oxide material (e.g., silicon dioxide germanium dioxide, or SiGe oxide) on nanoribbons 104, and a layer of high-k dielectric material (e.g., hafnium oxide or aluminum oxide) on the native oxide.

According to some embodiments, spacer structures 110 and inner spacers 112 are present along the sidewalls of the gate structures. Spacer structures 110 and inner spacers 112 may be any suitable dielectric material, such as silicon nitride, and provide separation between a given gate structure and the adjacent source or drain region 106. Inner spacers 112 may separate adjacent nanoribbons 104 from one another along a third direction (e.g., a vertical direction).

According to some embodiments, a dielectric fill 114 may be present over the source or drain regions 106 within the corresponding source/drain trenches of semiconductor devices 101. A top surface of dielectric fill 114 may be substantially co-planar with a top surface of spacer structures 110. Dielectric fill 114 may include any suitable dielectric material, such as silicon dioxide, in some examples.

According to some embodiments, any number of frontside contacts 116 are provided through dielectric fill 114 and contacting a top portion of source or drain regions 106. Frontside contacts 116 can include any suitable conductive material, such as tungsten, molybdenum, ruthenium, cobalt, or other metals. Frontside contacts 116 may be formed during the same metal deposition process(es) such that they all include the same conductive material.

According to some embodiments, one or more of source or drain regions 106 have a dielectric cap 118 on its bottom surface. Dielectric cap 118 may extend through a portion of base dielectric layer 102. Dielectric caps 118 may directly contact the bottommost surfaces of their corresponding source or drain regions 106 and may include any suitable dielectric material having sufficient etch selectivity to the dielectric material of base dielectric layer 102. Example materials for dielectric cap 118 include silicon nitride or silicon oxynitride.

According to some embodiments, a backside contact 120 is provided beneath a corresponding gate structure. In the illustrated example, backside contact 120 directly contacts the bottom surface of the middle gate electrode 108. Backside contact 120 may include any of the same materials noted above for frontside contacts 116. In some examples, backside contact 120 and frontside contacts 116 include the same conductive material. Backside contact 120 may connect to backside power or ground rails, or to a signal routing interconnect structure. According to some embodiments, additional dielectric layers and conductive elements can be formed beneath base dielectric layer 102 to create a backside interconnect structure (such as a power delivery network and/or signal routing network).

According to some embodiments, a dielectric liner 122 is present around portions of backside contact 120, such as between backside contact 120 and base dielectric layer 102. Dielectric liner 122 may be formed within a backside cavity prior to the formation of backside contact 120, such that backside contact 120 punches through a portion of dielectric liner 122 to contact the bottom of the gate structure. In some embodiments, backside contact 120 also punches through gate dielectric 109 to directly contact gate electrode 108. Dielectric liner 122 may be any suitable dielectric material, such as silicon nitride, silicon oxycarbonitride, aluminum oxide, or titanium nitride. Dielectric liner 122 may have a thickness of less than 5 nm, or between 1 nm and 3 nm.

According to some embodiments, the width of backside contact 120 tapers inwards as it rises towards the bottom surface of gate electrode 108. As noted above, this tapering may be caused by the backside RIE process to form the cavity beneath the gate structure. In some examples, a first width (w1) of backside contact 120 along the first direction at the bottom surface of base dielectric layer 102 is greater than a second width (w2) of backside contact 120 along the first direction at the bottom surface of the gate structure by at least 3 nm. Backside contact 120 is lithographically aligned to land on the bottom surface of the gate structure, which itself has a width (w3) along the first direction that is less than 30 nm, such as between 15 nm and 25 nm.

### Fabrication Methodology

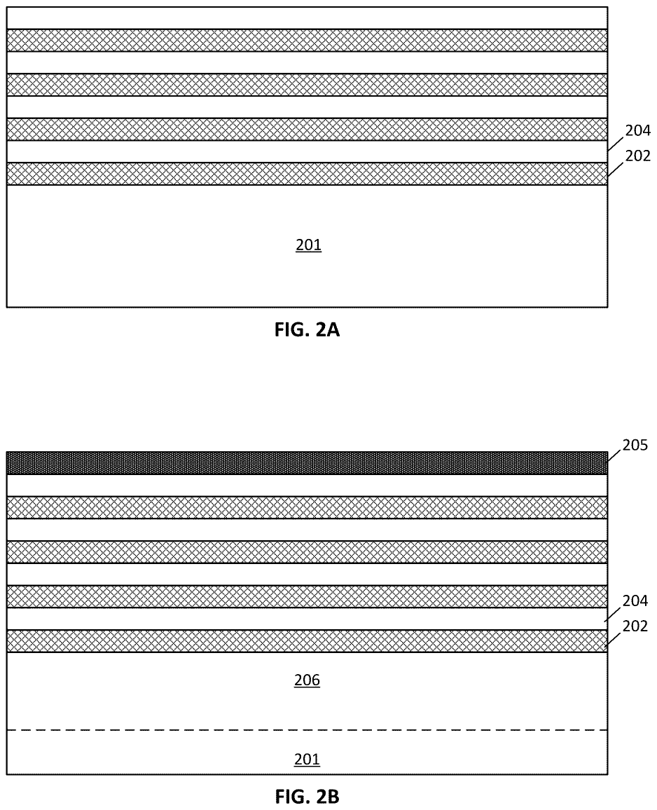

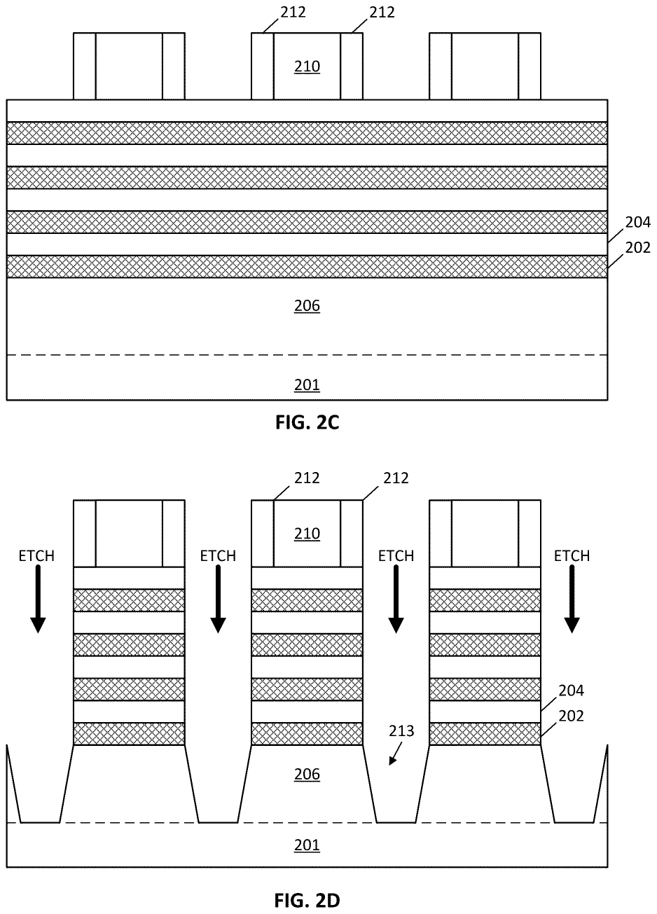

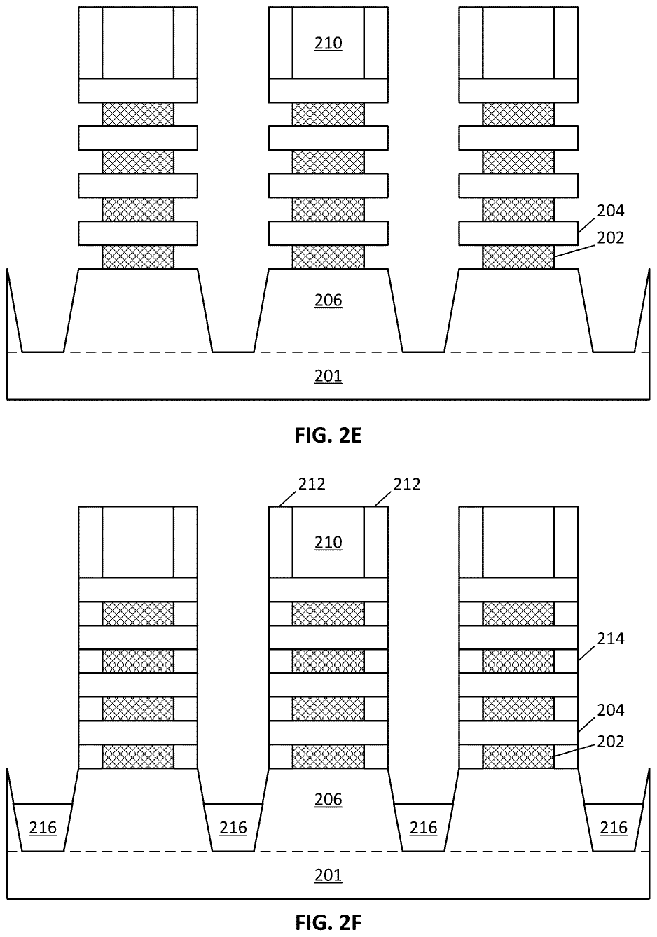

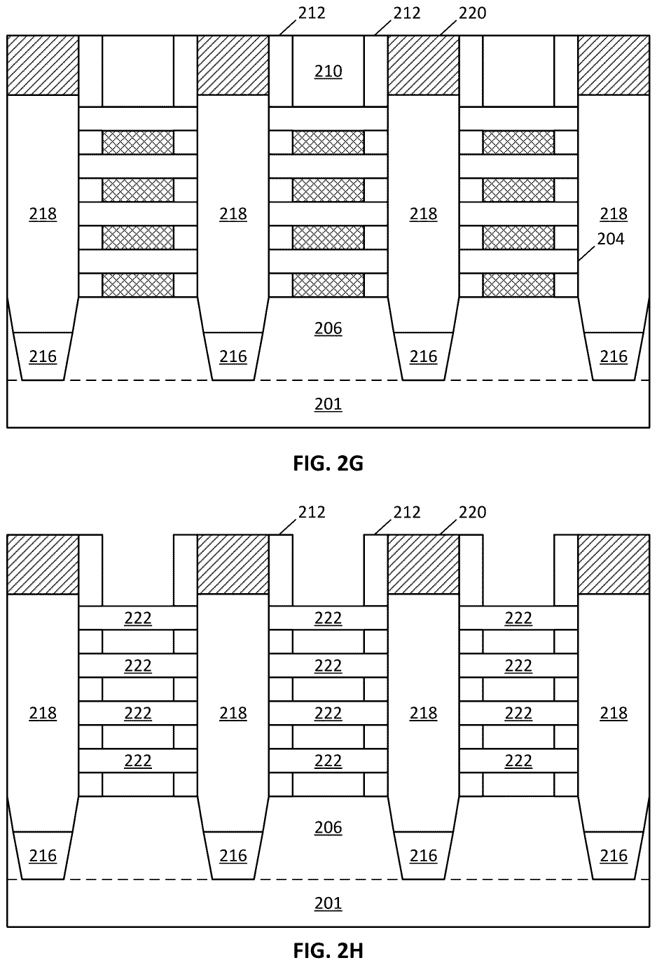

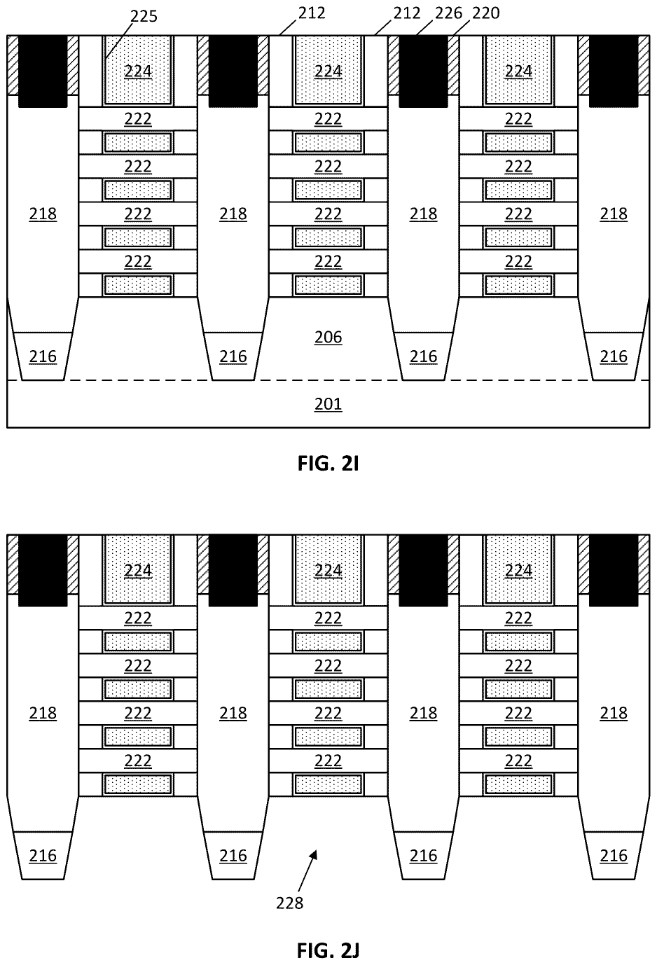

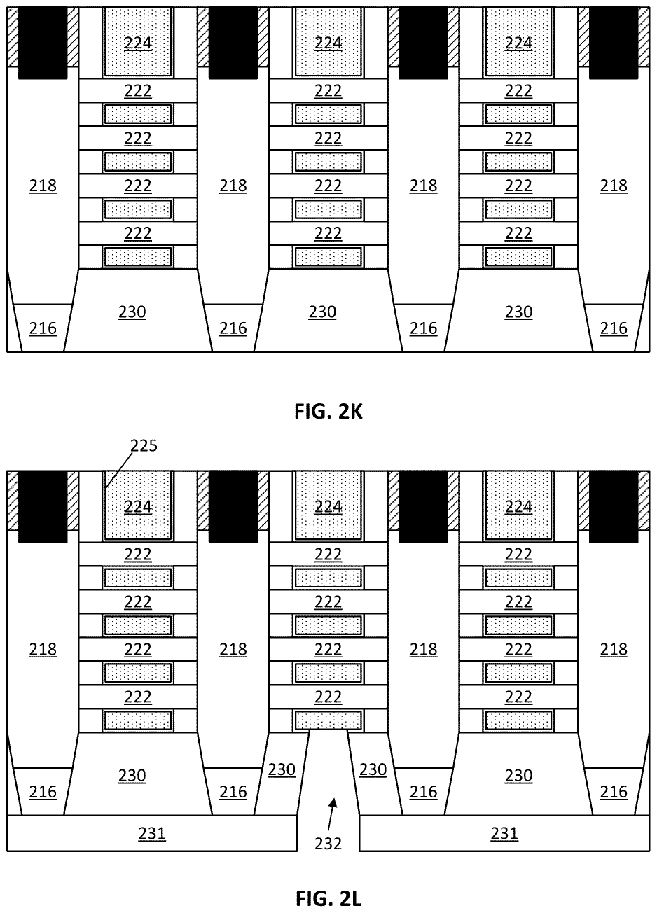

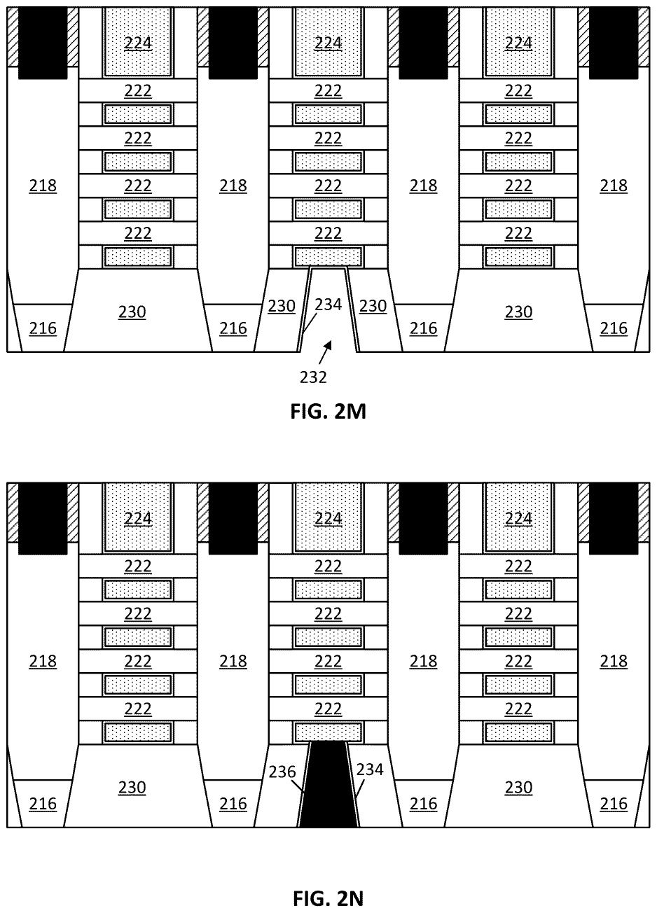

FIG. 2A-2N include cross-sectional views that collectively illustrate an example process for forming an integrated circuit configured with a backside contact beneath a corresponding gate structure, in accordance with an embodiment of the present disclosure. FIG. 2A-2N represent a similar cross-sectional view as that of FIG. 1 across a series of semiconductor devices. The depicted structure evolves as the process flow continues, culminating in the structure shown in FIG. 2N, which is similar to the structure shown in FIG. 1. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure. Although only a single backside contact is shown in the fabrication process, it should be understood that any number of backside contacts can be formed across the integrated circuit using the same process described herein.

FIG. 2A illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

FIG. 2B depicts a cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. Cap layer 205 extends along the top of each fin in a first direction.

According to some embodiments, an anisotropic etching process through the layer stack continues into at least a portion of substrate 201. Portions of substrate 201 beneath the fins are not etched and yield subfin regions 206. The etched portions of substrate 201 that are not under the fins may be filled with a dielectric fill that acts as shallow trench isolation (STI) between adjacent fins. The dielectric fill is not shown in these cross-sections as it extends in the first direction along the sides of subfin regions 206 that are into and out of the page. The dielectric fill may be any suitable dielectric material such as silicon dioxide. The subfin regions 206 represent remaining portions of substrate 201 flanked by the dielectric fill, according to some embodiments.

FIG. 2C depicts a cross-section view of the structure shown in FIG. 2B following the formation of sacrificial gates 210 and spacer structures 212, according to some embodiments. A gate masking layer may first be patterned in strips that extend orthogonally across each of the fins (e.g., in a second direction) in order to form corresponding sacrificial gates 210 in strips beneath the gate masking layers. Afterwards, the gate masking layers may be removed or may remain as a cap layer above each sacrificial gate 210. According to some embodiments, the sacrificial gate material is removed in all areas not protected by the gate masking layers. Sacrificial gate 210 may be any suitable material that can be selectively removed without damaging the semiconductor material of the fins. In some examples, sacrificial gate 210 includes polysilicon.

According to some embodiments, spacer structures 212 are formed along the sidewalls of sacrificial gates 210. Spacer structures 212 may be conformally deposited (e.g., using CVD or ALD) and then etched back or otherwise removed (e.g., via anisotropic or directional etch) from horizontal surfaces, such that spacer structures 212 remain mostly on sidewalls of any exposed structures. The width of spacer structures 212 (along the first direction) may vary from one example to the next, but in some cases is in the range of 3 nm to 20 nm. According to some embodiments, spacer structures 212 may be any suitable dielectric material, such as silicon nitride, silicon carbon nitride, or silicon oxycarbonitride. In one such embodiment, spacer structures 212 comprise a nitride and the dielectric fill adjacent to subfin regions 206 comprises an oxide, so as to provide a degree of etch selectivity during final gate processing.

FIG. 2D depicts a cross-section view of the structure shown in FIG. 2C following the removal of exposed portions of the fins not protected by sacrificial gates 210 and spacer structures 212, according to some embodiments. The exposed fin portions may be removed using any anisotropic etching process, such as RIE or other directional etch process. The removal of the exposed fin portions creates source/drain trenches that alternate with gate trenches (currently filled with sacrificial gates 210) along the first direction, according to some embodiments. In some embodiments, at least a portion of subfin regions 206 is also removed such that a top surface of subfin regions 206 is recessed below a top surface of the adjacent dielectric fill. In some embodiments, subfin regions 206 within the source/drain trenches are removed entirely (as illustrated), to yield subfin cavities 213. Note that due to the deep etching process, the source/drain trenches may exhibit a tapering width as they extend deeper. Accordingly, at least subfin cavities 213 may have a tapering width, as illustrated.

FIG. 2E depicts a cross-section view of the structure shown in FIG. 2D following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

FIG. 2F depicts a cross-section view of the structure shown in FIG. 2E following the formation of internal spacers 214, according to an embodiment of the present disclosure. Internal spacers 214 may have a material composition that is similar to or the exact same as spacer structures 212. Accordingly, internal spacers 214 may be any suitable dielectric material that exhibits high etch selectively to semiconductor materials such as silicon and/or silicon germanium. Internal spacers 214 may be, for example, conformally deposited over the sides of the fin structure using a conformal deposition process like CVD or ALD and then etched back using an isotropic etching process to expose the ends of semiconductor layers 204. According to some embodiments, internal spacers 214 have a similar width (e.g., along the first direction) to spacer structures 212. According to some embodiments, a portion of the dielectric material used to form internal spacers 214 remains at the bottom of the source/gate trenches as one or more dielectric caps 216. Accordingly, each of dielectric caps 216 may have the same material composition as internal spacers 214. Dielectric caps 216 may fill a portion of subfin cavities 213 and may exhibit the same tapering width profile as subfin cavities 213.

FIG. 2G depicts a cross-section view of the structure shown in FIG. 2F following the formation of source or drain regions 218 within the source/drain trenches, according to some embodiments. Source or drain regions 218 may be formed in the areas that had been previously occupied by the exposed fins between spacer structures 212. According to some embodiments, source or drain regions 218 are epitaxially grown from the exposed semiconductor material at the ends of semiconductor layers 204. Note that lower portions of source or drain regions 218 may also be grown from the exposed sidewalls surfaces of subfin region 206. According to some embodiments, source or drain regions 218 are formed directly over dielectric caps 216, such that dielectric caps 216 contact the bottom surfaces of source or drain regions 218.

According to some embodiments, a dielectric fill 220 is provided over source or drain regions 218. In some examples, dielectric fill 220 occupies a remaining volume within the source/drain trenches around and over portions of source or drain regions 218. Dielectric fill 220 may be any suitable dielectric material, such as silicon dioxide. In some examples, dielectric fill 220 extends up to and planar with a top surface of spacer structures 212 (e.g., following a polishing procedure).

FIG. 2H depicts a cross-section view of the structure shown in FIG. 2G following the removal of sacrificial gates 210 and sacrificial layers 202, according to some embodiments. In examples where gate masking layers are still present, they may be removed at this time. Once sacrificial gates 210 are removed, the remaining fin portions extending between spacer structures 212 are exposed.

In the example where the fins include alternating sacrificial layers 202 and semiconductor layers 204, sacrificial layers 202 are selectively removed to leave behind nanoribbons 222 extending between corresponding source or drain regions 218. Each vertical set of nanoribbons 222 represents the semiconductor region (also called channel region) of a different semiconductor device. It should be understood that any of nanoribbons 222 may also be nanowires or nanosheets. Sacrificial gates 210 and sacrificial layers 202 may be removed using the same isotropic etching process or different isotropic etching processes.

FIG. 2I depicts a cross-section view of the structure shown in FIG. 2H following the formation of gate structures around the suspended nanoribbons 222, according to an embodiment of the present disclosure. As noted above, each gate structure includes a gate electrode 224 on a gate dielectric 225.

The gate dielectric 225 may be conformally deposited around nanoribbons 222 using any suitable deposition process, such as ALD. Gate dielectric 225 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 225 is hafnium oxide with a thickness between about 1 nm and about 5 nm. In some embodiments, gate dielectric 225 may include one or more silicates (e.g., titanium silicate, tungsten silicate, niobium silicate, and silicates of other transition metals). Gate dielectric 225 may be a multilayer structure, in some examples. For instance, gate dielectric 225 may include a first layer on the nanoribbons, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 225 to improve its quality when a high-k dielectric material is used. In some embodiments, the high-k material can be nitridized to improve its aging resistance.

The gate electrode 224 may be deposited over gate dielectric 225 and can be any standard or proprietary conductive material that may include any number of gate cuts. In some embodiments, gate electrode 224 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 224 may include, for instance, one or more workfunction layers, resistance-reducing layers, and/or barrier layers. P-type workfunction layers include, for example, tungsten, and n-type workfunction layers include, for example, titanium nitride or titanium aluminum carbide.

According to some embodiments, frontside contacts 226 may be formed through dielectric fill 220 to contact the top surfaces of source or drain regions 218. Frontside contacts 226 may include any suitable conductive material, such as tungsten, cobalt, molybdenum, or ruthenium, for making electrical contact with the underlying source or drain regions 218. Although not illustrated, any number of frontside interconnect layers may be formed over the semiconductor devices. The interconnect layers include dielectric layers, conductive vias, and conductive layers to carry power and/or signals to various transistor elements.

FIG. 2J depicts a cross-section view of the structure shown in FIG. 2I following the removal of substrate 201. Any number of polishing, grinding, or etching processes may be used to remove the bulk portion of substrate 201. According to some embodiments, substrate 201 is removed until a bottom surface of dielectric caps 216 and/or a bottom surface of the dielectric fill adjacent to subfin regions 206 are exposed. The backside exposed subfin regions 206 may then be etched away using any suitable isotropic etching process. According to some embodiments, the removal of subfin regions 206 yields backside recesses 228 between portions of source or drain regions 218 with dielectric caps 216 at their tips extending downward away from the bottom surface of the gate structures.

FIG. 2K depicts a cross-section view of the structure shown in FIG. 2J following the formation of a base dielectric structure 230 within backside recesses 228, according to some embodiments. One or more dielectric materials or layers may be deposited to form base dielectric structure 230. Furthermore, base dielectric structure 230 may also include the dielectric fill adjacent to backside recesses 228 into and out of the page. Base dielectric structure 230 may include any suitable dielectric material, such as silicon dioxide. According to some embodiments, a bottom surface of base dielectric structure 230 may be polished to be a substantially planar surface. The planar bottom surface of base dielectric structure 230 may be coplanar with a bottom surface of dielectric caps 216.

FIG. 2L depicts a cross-section view of the structure shown in FIG. 2K following the formation of a masking layer 231 on the backside of the structure, according to some embodiments. Masking layer 231 may be a photoresist material or a dielectric material that has a high etch selectivity with the dielectric material of base dielectric structure 230.

According to some embodiments, masking layer 231 is patterned and etched to form an opening through masking layer 231 beneath a corresponding gate structure. A subsequent directional etching process may then be performed to create a backside cavity 232 through base dielectric structure 230, according to some embodiments. An RIE process may be used to anisotropically etch through the exposed portions of base dielectric structure 230 not protected by masking layer 231. As a result of the etching process, backside cavity 232 has a tapering profile with a width that decreases from the opening of the cavity (e.g., at the bottom surface of base dielectric structure 230) towards the bottom surface of the gate structure, according to some embodiments. According to some embodiments, the etching process also removes a portion of gate dielectric 225 to expose a bottom surface of gate electrode 224 within cavity 232. In some examples, backside cavity 232 has a greatest width along the bottom surface of base dielectric structure 230 that is between about 15 nm and about 20 nm and a smallest width at the bottom surface of the gate structure that is between about 10 nm and about 15 nm. Due to standard alignment error, the alignment of backside cavity 232 beneath the gate structure may not be perfect such that backside cavity 232 may be offset along the first direction from the center of gate electrode 224 by, for example, up to 5 nm.

FIG. 2M depicts a cross-section view of the structure shown in FIG. 2L following the formation of a dielectric liner 234, according to some embodiments. Dielectric liner 234 may be any suitable dielectric material, such as silicon nitride, aluminum oxide, or titanium nitride, and may have a thickness between about 1 nm and about 3 nm. Dielectric liner 234 may be deposited using any suitable conformal deposition technique, such as chemical vapor deposition (CVD), plasma-enhanced chemical vapor deposition (PECVD), or atomic layer deposition (ALD). Dielectric liner 234 may be formed such that is covers the sidewalls of cavity 232 and the exposed bottom surface of either gate dielectric 225 or gate electrode 224. In some examples, portions of dielectric liner 234 deposited along the bottom surface of base dielectric structure 230 are removed (e.g., via chemical mechanical polishing). In some other examples, portions of dielectric liner 234 continue to extend along the bottom surface of base dielectric structure 230.

FIG. 2N depicts a cross-section view of the structure shown in FIG. 2M following the formation of a backside contact 236 within backside cavity 232, according to some embodiments. Backside contact 236 may include any suitable conductive material, such as any of tungsten, ruthenium, molybdenum, or cobalt. Prior to the deposition of conductive material to form backside contact 236, a directional etch (e.g., RIE) is performed to punch through the portion of dielectric liner 234 on the bottom surface of the gate structure, according to some embodiments. In some examples, this directional etch also punches through gate dielectric 225, if it is still present, to expose the bottom surface of gate electrode 224. In any case, backside contact 236 is formed directly on the bottom surface of gate electrode 224, according to some embodiments. Due to the tapering profile, the width of backside contact 236 may be about 3 nm greater, or between 2 nm and 5 nm greater, at the bottom surface of base dielectric structure 230 compared to the bottom surface of the gate structure. In some examples, backside contact 236 has a greatest width along the bottom surface of base dielectric structure 230 that is between about 15 nm and about 20 nm and a smallest width at the bottom surface of the gate structure that is between about 10 nm and about 15 nm. As noted above, alignment error when performing the etching process may cause backside contact 236 to be offset from the center of the gate structure along the first direction by up to 3 nm or up to 5 nm.

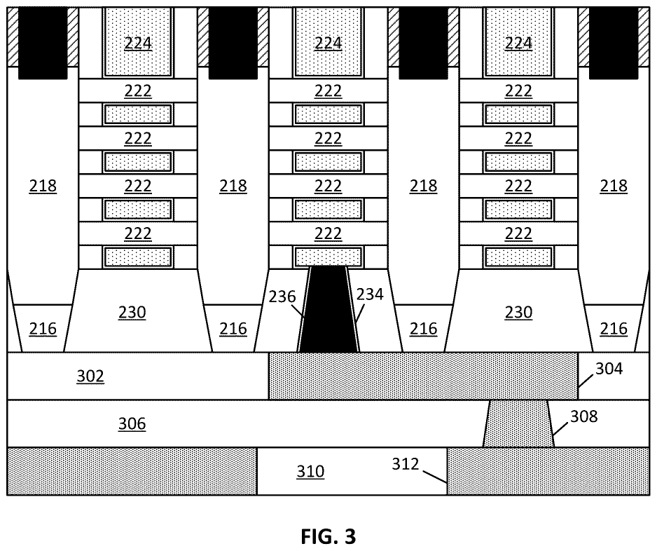

Any number of backside interconnect layers may be formed to provide a connection to backside contact 236. FIG. 3 illustrates a cross-section view of the structure from FIG. 2N, which includes a backside interconnect region made up of several interconnect layers, according to some embodiments. A first backside interconnect layer includes a first backside dielectric layer 302 and a first conductive trace 304. First conductive trace 304 may contact a bottom surface of backside contact 236. A second backside interconnect layer may include a second backside dielectric layer 306 and a conductive via 308 that contacts a portion of first conductive trace 304. A third backside interconnect layer may include a third backside dielectric layer 310 and a second conductive trace 312. Conductive via 308 may extend through the thickness of second backside dielectric layer 306 to contact both first conductive trace 304 and second conductive trace 312. Each of first backside dielectric layer 302, second backside dielectric layer 306, and third backside dielectric layer 310 may be any suitable dielectric material, such as silicon dioxide. Each of first conductive trace 304, second conductive trace 312, and conductive via 308 may be any suitable conductive material, such as any of tungsten, ruthenium, copper, molybdenum, or cobalt.

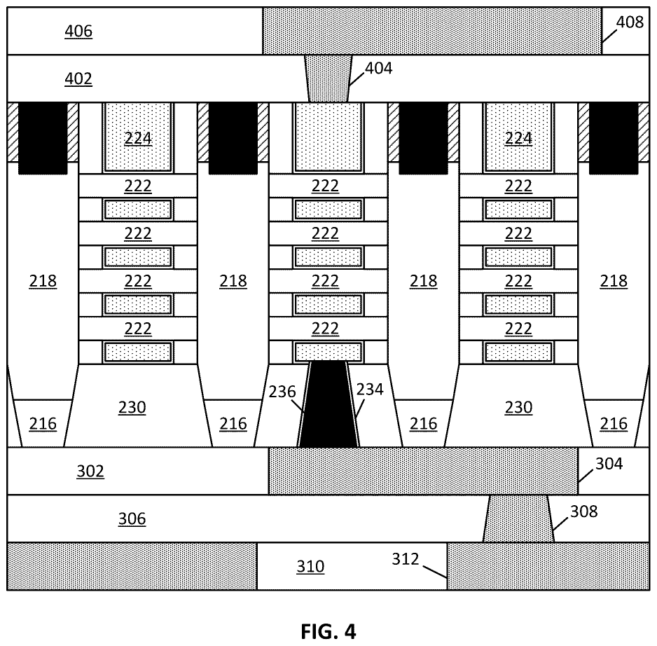

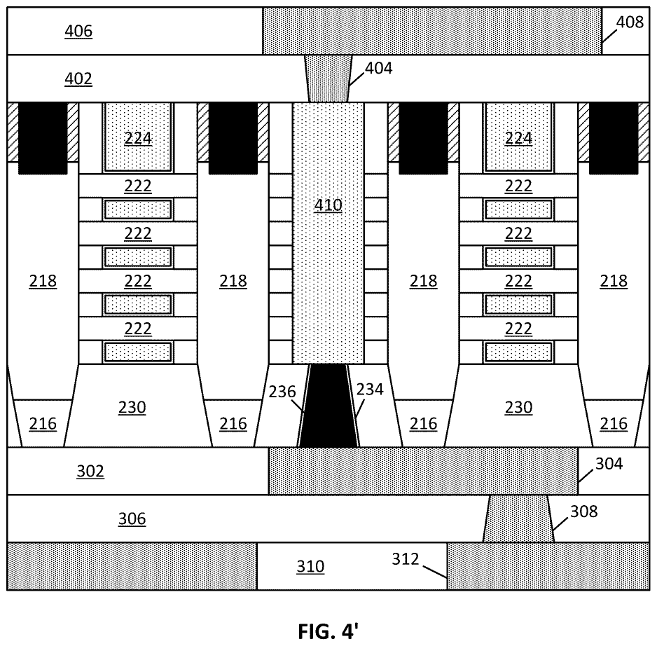

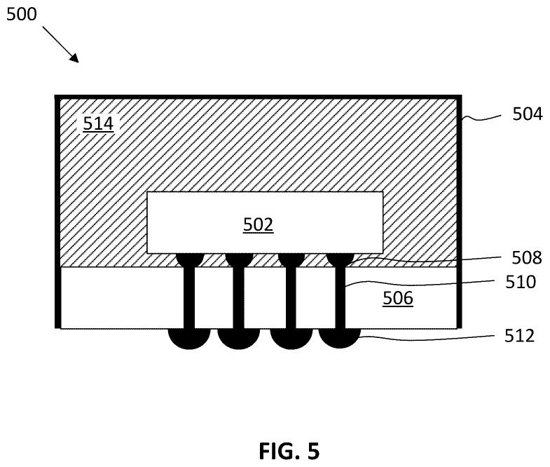

In some embodiments, a frontside contact is formed over the same gate structure that includes a backside contact. FIG. 4 illustrates a cross-section view of the structure from FIG. 3 that shows a frontside interconnect region made up of several interconnect layers. According to some embodiments, the frontside interconnect region includes a first frontside interconnect layer having a first frontside dielectric layer 402 and a frontside via 404. Frontside via 404 may contact a top surface of the gate structure, such that the gate structure extends between both frontside via 404 and backside contact 236. A second frontside interconnect layer includes a second frontside dielectric layer 406 and a frontside conductive trace 408. According to some embodiments, the gate structure between frontside via 404 and backside contact 236 may be a dummy gate (e.g., a conductive structure that does not act as a switching transistor), to pass signals between the backside interconnect region and the frontside interconnect region. FIG. 4′ illustrates another example structure similar to FIG. 4, but with nanoribbons 222 removed such that they do not pass through a conductive structure 410. In this example, conductive structure 410 extends between frontside via 404 and backside contact 236 to act as a feedthrough structure to pass signals between the backside interconnect region and the frontside interconnect region. Conductive structure 410 may otherwise be similar to any other gate structures and can include the same materials as noted above for gate electrode 224.

FIG. 5 illustrates an example embodiment of a chip package 500, in accordance with an embodiment of the present disclosure. As can be seen, chip package 500 includes one or more dies 502. One or more dies 502 may include at least one integrated circuit having semiconductor devices, such as any of the semiconductor devices disclosed herein. One or more dies 502 may include any other circuitry used to interface with other devices formed on the dies, or other devices connected to chip package 500, in some example configurations.

As can be further seen, chip package 500 includes a housing 504 that is bonded to a package substrate 506. The housing 504 may be any standard or proprietary housing, and may provide, for example, electromagnetic shielding and environmental protection for the components of chip package 500. The one or more dies 502 may be conductively coupled to a package substrate 506 using connections 508, which may be implemented with any number of standard or proprietary connection mechanisms, such as solder bumps, ball grid array (BGA), pins, or wire bonds, to name a few examples. Package substrate 506 may be any standard or proprietary package substrate, but in some cases includes a dielectric material having conductive pathways (e.g., including conductive vias and lines) extending through the dielectric material between the faces of package substrate 506, or between different locations on each face. In some embodiments, package substrate 506 may have a thickness less than 1 millimeter (e.g., between 0.1 millimeters and 0.5 millimeters), although any number of package geometries can be used. Additional conductive contacts 512 may be disposed at an opposite face of package substrate 506 for conductively contacting, for instance, a printed circuit board (PCB). One or more vias 510 extend through a thickness of package substrate 506 to provide conductive pathways between one or more of connections 508 to one or more of contacts 512. Vias 510 are illustrated as single straight columns through package substrate 506 for ease of illustration, although other configurations can be used (e.g., damascene, dual damascene, through-silicon via, or an interconnect structure that meanders through the thickness of substrate 506 to contact one or more intermediate locations therein). In still other embodiments, vias 510 are fabricated by multiple smaller stacked vias, or are staggered at different locations across package substrate 506. In the illustrated embodiment, contacts 512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 512, to inhibit shorting.

In some embodiments, a mold material 514 may be disposed around the one or more dies 502 included within housing 504 (e.g., between dies 502 and package substrate 506 as an underfill material, as well as between dies 502 and housing 504 as an overfill material). Although the dimensions and qualities of the mold material 514 can vary from one embodiment to the next, in some embodiments, a thickness of mold material 514 is less than 1 millimeter. Example materials that may be used for mold material 514 include epoxy mold materials, as suitable. In some cases, the mold material 514 is thermally conductive, in addition to being electrically insulating.

### Methodology

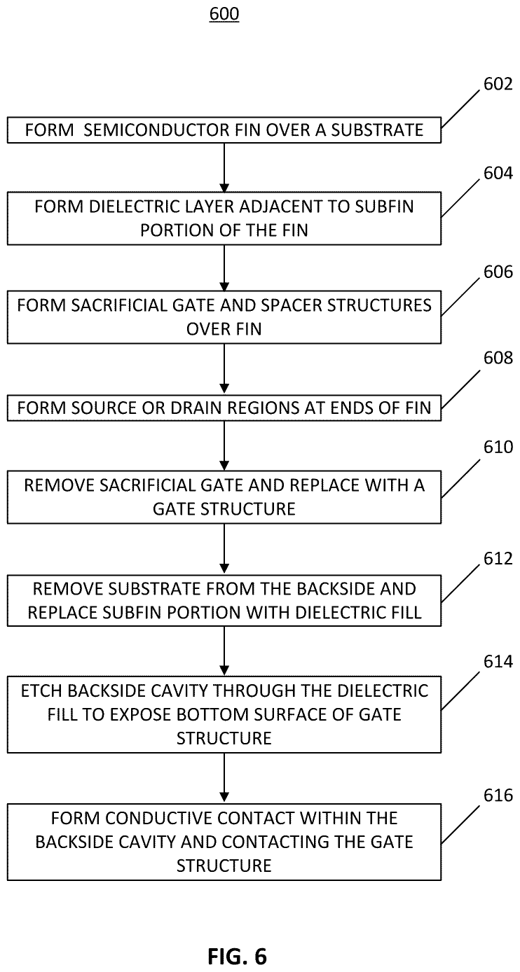

FIG. 6 is a flow chart of a method 600 for forming at least a portion of an integrated circuit, according to an embodiment. Various operations of method 600 may be illustrated in FIG. 2A-2N. However, the correlation of the various operations of method 600 to the specific components illustrated in the aforementioned figures is not intended to imply any structural and/or use limitations. Rather, the aforementioned figures provide one example embodiment of method 600. Other operations may be performed before, during, or after any of the operations of method 600. For example, method 600 does not explicitly describe various standard processes that are usually performed to form transistor structures. Some of the operations of method 600 may be performed in a different order than the illustrated order.

Method 600 begins with operation 602 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

Method 600 continues with operation 604 where a dielectric layer is formed around subfin portions of at least one of the fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 600 continues with operation 606 where a sacrificial gate is formed over at least one of the fins. The sacrificial gate may be patterned using a gate masking layer in a strip that runs orthogonally over the at least one fin, Multiple gate masking layers may be formed that run parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fin. In one example, the sacrificial gate includes polysilicon.

According to some embodiments, spacer structures are also formed on sidewalls of at least the sacrificial gate. The spacer structures may be deposited and then etched back such that the spacer structures remain mostly only on sidewalls of any exposed structures. In some cases, spacer structures may also be formed along sidewalls of the exposed fin running orthogonally between strips of sacrificial gates. According to some embodiments, the spacer structures may be any suitable dielectric material, such as silicon nitride or silicon oxynitride.

Method 600 continues with operation 608 where source or drain regions are formed at opposite ends of the fin. Any exposed portions of the fin not covered by the sacrificial gate or spacer structures may be removed using any anisotropic etching process, such as reactive ion etching (RIE). Once the exposed fin portions have been removed, the source or drain regions may be formed in the areas that had been previously occupied by the exposed fin portions between the spacer structures. According to some embodiments, the source or drain regions are epitaxially grown from the exposed semiconductor material of the fin (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 600 continues with operation 610 where gate structures are formed over the semiconductor material of the semiconductor fin. The sacrificial gate is first removed along with any sacrificial layers within the exposed fin between the spacer structures (in the case of GAA structures). The gate structure may then be formed in place of the sacrificial gate. The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

Method 600 continues with operation 612 where the substrate is removed from the backside of the structure to expose the bottom surface of the subfin portions and/or the bottom surface of the dielectric layer adjacent to the subfin portions. The substrate may be removed using any number of isotropic etching, polishing, or grinding operations. The subfin portions may also be removed and replaced with any suitable dielectric material(s), such as silicon dioxide.

Method 600 continues with operation 614 where a backside cavity is formed through the dielectric material(s) on the backside to expose the bottom surface of the gate structure. The backside cavity may be formed using any suitable anisotropic etching technique, such as RIE. According to some embodiments, the backside cavity may have sidewalls that taper inwards towards the exposed bottom surface of the gate structure. In some examples, the backside cavity has a greatest width along the bottom surface of the dielectric material(s) that is between about 15 nm and about 20 nm and a smallest width at the bottom surface of the gate structure that is between about 10 nm and about 15 nm. Any number of adjacent backside cavities may be formed beneath adjacent gate structures where the adjacent backside cavities are spaced apart by a distance that is less than 20 nm or between about 12 nm and about 20 nm.

Method 600 continues with operation 616 where a backside contact is formed within the backside cavity. According to some embodiments, the backside contact is formed directly on exposed surface(s) of the gate structure (such as directly on the gate electrode). The backside contact may include any suitable conductive material, such as cobalt, ruthenium, molybdenum, or tungsten. According to some embodiments, the backside contact is part of a backside interconnect structure to connect the gate structure to a power or ground rail or to a signal track. Adjacent backside contacts (e.g., between adjacent gate structures) may have a shortest distance between them of less than 20 nm or between about 12 nm and about 20 nm. In some examples, a dielectric layer may be conformally deposited (e.g., ALD) prior to deposition of conductive contact materials, followed by an anisotropic punch-through etch to expose the bottom surface of the gate structure, as described above.

### Example System

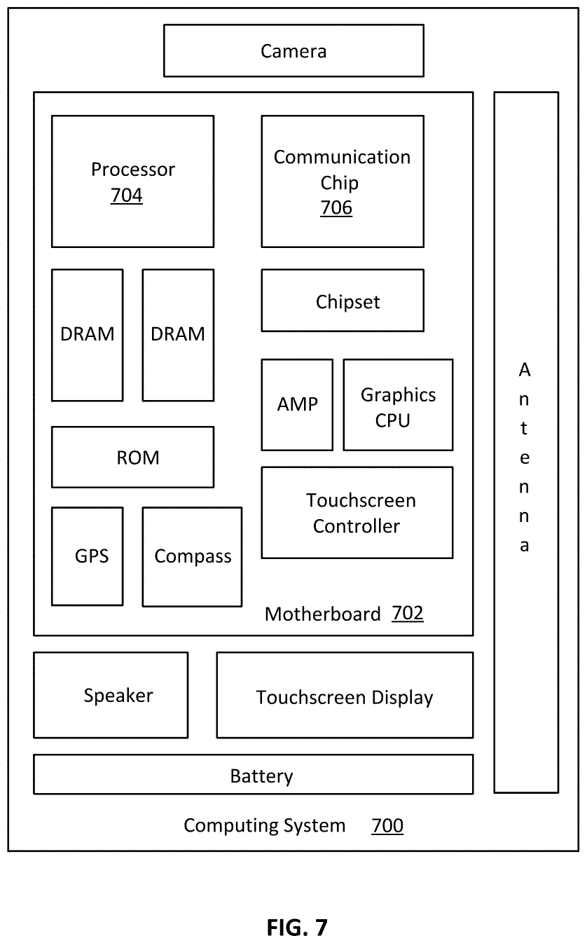

FIG. 7 is an example computing system implemented with one or more of the integrated circuit structures as disclosed herein, in accordance with some embodiments of the present disclosure. As can be seen, the computing system 700 houses a motherboard 702. The motherboard 702 may include a number of components, including, but not limited to, a processor 704 and at least one communication chip 706, each of which can be physically and electrically coupled to the motherboard 702, or otherwise integrated therein. As will be appreciated, the motherboard 702 may be, for example, any printed circuit board (PCB), whether a main board, a daughterboard mounted on a main board, or the only board of system 700, etc.

Depending on its applications, computing system 700 may include one or more other components that may or may not be physically and electrically coupled to the motherboard 702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 700 may include one or more integrated circuit structures or devices configured in accordance with an example embodiment (e.g., a module including one or more semiconductor devices that include directly patterned and etched backside contacts, as variously provided herein). In some embodiments, multiple functions can be integrated into one or more chips (e.g., for instance, note that the communication chip 706 can be part of or otherwise integrated into the processor 704).

The communication chip 706 enables wireless communications for the transfer of data to and from the computing system 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing system 700 includes an integrated circuit die packaged within the processor 704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 706 also may include an integrated circuit die packaged within the communication chip 706. In accordance with some such example embodiments, the integrated circuit die of the communication chip includes one or more semiconductor devices as variously described herein. As will be appreciated in light of this disclosure, note that multi-standard wireless capability may be integrated directly into the processor 704 (e.g., where functionality of any chips 706 is integrated into processor 704, rather than having separate communication chips). Further note that processor 704 may be a chip set having such wireless capability. In short, any number of processor 704 and/or communication chips 706 can be used. Likewise, any one chip or chip set can have multiple functions integrated therein.

In various implementations, the computing system 700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### Further Example Embodiments

The following examples pertain to further embodiments, from which numerous permutations and configurations will be apparent.

Example 1 is an integrated circuit that includes a semiconductor device having a semiconductor region extending in a first direction from a first source or drain region to a second source or drain region and a gate structure extending in a second direction, different from the first direction, over the semiconductor region, a dielectric layer beneath the gate structure, and a backside conductive contact extending through the dielectric layer and contacting a bottom surface of the gate structure. The backside conductive contact has a tapered width along the first direction such that a first width of the backside conductive contact at a bottom surface of the dielectric layer is greater than a second width of the backside conductive contact at the bottom surface of the gate structure.

Example 2 includes the integrated circuit of Example 1, further comprising a dielectric liner between the backside conductive contact and the dielectric layer.

Example 3 includes the integrated circuit of Example 2, wherein the dielectric liner comprises silicon and nitrogen.

Example 4 includes the integrated circuit of Example 2, wherein the dielectric liner comprises aluminum and oxygen.

Example 5 includes the integrated circuit of any one of Examples 2-4, wherein at least a portion of the dielectric liner contacts at least a portion of the bottom surface of the gate structure.

Example 6 includes the integrated circuit of any one of Examples 1-5, wherein the first width is at least 3 nm greater than the second width.

Example 7 includes the integrated circuit of any one of Examples 1-6, wherein the gate structure comprises a gate dielectric and a gate electrode on the gate dielectric.

Example 8 includes the integrated circuit of Example 7, wherein the backside conductive contact extends across a thickness of the gate dielectric and directly contacts the gate electrode.

Example 9 includes the integrated circuit of Example 7 or 8, wherein the backside conductive contact comprises a same conductive material as the gate electrode.

Example 10 includes the integrated circuit of any one of Examples 1-9, wherein the dielectric layer is a first dielectric layer and the integrated circuit further comprises a second dielectric layer above the gate structure and a frontside conductive contact extending through the second dielectric layer and contacting a top surface of the gate structure.

Example 11 includes the integrated circuit of any one of Examples 1-10, wherein the gate structure has a width along the first direction that is no greater than 30 nm.

Example 12 includes the integrated circuit of any one of Examples 1-11, wherein the semiconductor region comprises a plurality of semiconductor nanoribbons.

Example 13 includes the integrated circuit of Example 12, wherein the plurality of semiconductor nanoribbons comprise germanium, silicon, or a combination thereof.

Example 14 is a die that includes the integrated circuit of any one of Examples 1-13.

Example 15 is an electronic device that includes a chip package having one or more dies. At least one of the one or more dies includes a semiconductor region extending in a first direction from a first source or drain region to a second source or drain region, a gate structure extending in a second direction, different from the first direction, over the semiconductor region, a dielectric layer beneath the gate structure, and a backside conductive contact extending through the dielectric layer and contacting a bottom surface of the gate structure. The gate structure has a width along the first direction that is no greater than 30 nm.

Example 16 includes the electronic device of Example 15, wherein the at least one of the one or more dies further comprises a dielectric liner between the backside conductive contact and the dielectric layer.

Example 17 includes the electronic device of Example 16, wherein the dielectric liner comprises silicon and nitrogen.

Example 18 includes the electronic device of Example 16, wherein the dielectric liner comprises aluminum and oxygen.

Example 19 includes the electronic device of any one of Examples 16-18, wherein at least a portion of the dielectric liner contacts at least a portion of the bottom surface of the gate structure.

Example 20 includes the electronic device of any one of Examples 15-19, wherein the gate structure comprises a gate dielectric and a gate electrode on the gate dielectric.

Example 21 includes the electronic device of Example 20, wherein the backside conductive contact extends across a thickness of the gate dielectric and directly contacts the gate electrode.

Example 22 includes the electronic device of Example 20 or 21, wherein the backside conductive contact comprises a same conductive material as the gate electrode.

Example 23 includes the electronic device of any one of Examples 15-22, wherein the dielectric layer is a first dielectric layer and the at least one of the one or more dies further comprises a second dielectric layer above the gate structure and a frontside conductive contact extending through the second dielectric layer and contacting a top surface of the gate structure.

Example 24 includes the electronic device of any one of Examples 15-23, wherein the backside conductive contact has a tapered width along the first direction such that a first width of the backside conductive contact at a bottom surface of the dielectric layer is greater than a second width of the backside conductive contact at the bottom surface of the gate structure.

Example 25 includes the electronic device of Example 24, wherein the first width is at least 3 nm greater than the second width.

Example 26 includes the electronic device of any one of Examples 15-25, wherein the semiconductor region comprises a plurality of semiconductor nanoribbons.

Example 27 includes the electronic device of Example 26, wherein the plurality of semiconductor nanoribbons comprise germanium, silicon, or a combination thereof.

Example 28 includes the electronic device of any one of Examples 15-27, further comprising a printed circuit board, wherein the chip package is coupled to the printed circuit board.

Example 29 is a method that includes forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; forming a source or drain region at exposed ends of the semiconductor material and over the subfin; replacing the sacrificial gate with a gate structure; removing a portion of the substrate from a backside of the integrated circuit; removing the subfin from the backside and replacing the subfin with a dielectric fill; etching a cavity through the dielectric fill such that a bottom surface of the gate structure is exposed; and forming a conductive contact in the cavity.

Example 30 includes the method of Example 29, wherein etching the cavity comprises etching the cavity using reactive ion etching (RIE).

Example 31 includes the method of Example 29 or 30, wherein the dielectric fill comprises the same material composition as the dielectric layer.

Example 32 includes the method of any one of Examples 29-31, wherein the gate structure comprises a gate dielectric and a gate electrode on the gate dielectric. The method further includes forming a dielectric liner in the cavity; removing a portion of the dielectric liner on the bottom surface of the gate structure; and etching through the gate dielectric within the cavity to expose the gate electrode.

Example 33 includes the method of Example 32, wherein forming the conductive contact comprises forming the conductive contact on the dielectric liner and directly on the gate electrode.

Example 34 is an integrated circuit that includes a first semiconductor device having a first semiconductor region extending in a first direction from a first source or drain region, a second semiconductor device having a second semiconductor region extending in the first direction from a second source or drain region, a conductive structure between the first source or drain region and the second source or drain region along the first direction, a first dielectric layer beneath the conductive structure, a second dielectric layer above the conductive structure, a backside conductive contact extending through the first dielectric layer and contacting a bottom surface of the conductive structure, and a frontside conductive contact extending through the second dielectric layer and contacting a top surface of the conductive structure. The backside conductive contact has a tapered width along the first direction such that a first width of the backside conductive contact at a bottom surface of the first dielectric layer is greater than a second width of the backside conductive contact at the bottom surface of the conductive structure.

Example 35 includes the integrated circuit of Example 34, further comprising a dielectric liner between the backside conductive contact and the first dielectric layer.

Example 36 includes the integrated circuit of Example 35, wherein the dielectric liner comprises silicon and nitrogen.

Example 37 includes the integrated circuit of Example 35, wherein the dielectric liner comprises aluminum and oxygen.

Example 38 includes the integrated circuit of any one of Examples 35-37, wherein at least a portion of the dielectric liner contacts at least a portion of the bottom surface of the conductive structure.

Example 39 includes the integrated circuit of any one of Examples 34-38, wherein the first width is at least 3 nm greater than the second width.

Example 40 includes the integrated circuit of any one of Examples 34-39, further comprising a third semiconductor region extending in the first direction from the first source or drain region to the second source or region, such that the third semiconductor region extends through the conductive structure.

Example 41 includes the integrated circuit of any one of Examples 34-40, wherein the backside conductive contact comprises a same conductive material as the conductive structure.

Example 42 includes the integrated circuit of any one of Examples 34-41, wherein the conductive structure has a width along the first direction that is no greater than 30 nm.

Example 43 includes the integrated circuit of any one of Examples 34-42, wherein the first semiconductor region comprises a first plurality of semiconductor nanoribbons and the second semiconductor region comprises a second plurality of semiconductor nanoribbons.

Example 44 includes the integrated circuit of Example 43, wherein the first plurality of semiconductor nanoribbons and the second plurality of semiconductor nanoribbons comprise germanium, silicon, or a combination thereof.

Example 45 is a die that includes the integrated circuit of any one of Examples 34-44.

It will be appreciated that in some embodiments, the various components of the computing system 700 may be combined or integrated in a system-on-a-chip (SoC) architecture. In some embodiments, the components may be hardware components, firmware components, software components or any suitable combination of hardware, firmware or software.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a first source or drain region to a second source or drain region, and a gate structure extending in a second direction, different from the first direction, over the semiconductor region;
a dielectric layer beneath the gate structure; and
a backside conductive contact extending through the dielectric layer and contacting a bottom surface of the gate structure,
wherein the backside conductive contact has a tapered width along the first direction such that a first width of the backside conductive contact at a bottom surface of the dielectric layer is greater than a second width of the backside conductive contact at the bottom surface of the gate structure.

2. The integrated circuit of claim 1, further comprising a dielectric liner between the backside conductive contact and the dielectric layer.

3. The integrated circuit of claim 2, wherein at least a portion of the dielectric liner contacts at least a portion of the bottom surface of the gate structure.

4. The integrated circuit of claim 1, wherein the first width is at least 3 nm greater than the second width.

5. The integrated circuit of claim 1, wherein the gate structure comprises a gate dielectric and a gate electrode on the gate dielectric.

6. The integrated circuit of claim 5, wherein the backside conductive contact extends across a thickness of the gate dielectric and directly contacts the gate electrode.

7. The integrated circuit of claim 1, wherein the gate structure has a width along the first direction that is no greater than 30 nm.

8. A die comprising the integrated circuit of claim 1.

9. An electronic device, comprising:
a chip package comprising one or more dies, at least one of the one or more dies comprising
a semiconductor region extending in a first direction from a first source or drain region to a second source or drain region;
a gate structure extending in a second direction, different from the first direction, over the semiconductor region;
a dielectric layer beneath the gate structure; and
a backside conductive contact extending through the dielectric layer and contacting a bottom surface of the gate structure,
wherein the gate structure has a width along the first direction that is no greater than 30 nm.

10. The electronic device of claim 9, wherein the at least one of the one or more dies further comprises a dielectric liner between the backside conductive contact and the dielectric layer.

11. The electronic device of claim 10, wherein at least a portion of the dielectric liner contacts at least a portion of the bottom surface of the gate structure.

12. The electronic device of claim 9, wherein the gate structure comprises a gate dielectric and a gate electrode on the gate dielectric, and the backside conductive contact extends across a thickness of the gate dielectric and directly contacts the gate electrode.

13. The electronic device of claim 9, wherein the dielectric layer is a first dielectric layer and the at least one of the one or more dies further comprises a second dielectric layer above the gate structure and a frontside conductive contact extending through the second dielectric layer and contacting a top surface of the gate structure.

14. The electronic device of claim 9, wherein the backside conductive contact has a tapered width along the first direction such that a first width of the backside conductive contact at a bottom surface of the dielectric layer is greater than a second width of the backside conductive contact at the bottom surface of the gate structure.

15. An integrated circuit comprising:
a first semiconductor device having a first semiconductor region extending in a first direction from a first source or drain region;
a second semiconductor device having a second semiconductor region extending in the first direction from a second source or drain region;
a conductive structure between the first source or drain region and the second source or drain region along the first direction;
a first dielectric layer beneath the conductive structure;
a second dielectric layer above the conductive structure;
a backside conductive contact extending through the first dielectric layer and contacting a bottom surface of the conductive structure; and
a frontside conductive contact extending through the second dielectric layer and contacting a top surface of the conductive structure,
wherein the backside conductive contact has a tapered width along the first direction such that a first width of the backside conductive contact at a bottom surface of the first dielectric layer is greater than a second width of the backside conductive contact at the bottom surface of the conductive structure.

16. The integrated circuit of claim 15, further comprising a dielectric liner between the backside conductive contact and the first dielectric layer.

17. The integrated circuit of claim 16, wherein at least a portion of the dielectric liner contacts at least a portion of the bottom surface of the conductive structure.

18. The integrated circuit of claim 15, further comprising a third semiconductor region extending in the first direction from the first source or drain region to the second source or region, such that the third semiconductor region extends through the conductive structure.

19. The integrated circuit of claim 15, wherein the conductive structure has a width along the first direction that is no greater than 30 nm.

20. A die comprising the integrated circuit of claim 15.
